(19) United States
(12) Patent Application Publication
(10) Pub. No.: US 2008/0169187 A1
(43) Pub. Date: Jul. 17, 2008

(54) Electrical Circuit for an Electrolyser and Method for Reducing the Electromagnetic Fields Near the Electrolyser

(75) Inventor: Joachim Lange, Tervuren (BE)

Correspondence Address: OBLON, SPIVAK, MCCLELLAND MAIER & NEUSTADT, P.C., 1940 DUKE STREET, ALEXANDRIA, VA, 22314, US

(73) Assignee: Solvay (Societe Anonmme), Brussels (BE)

(21) Appl. No.: 11/817,155

(22) PCT Filed: Mar. 1, 2006
(86) PCT No.: PCT/EP06/60368

§ 371 Date: Feb. 15, 2008

(30) Foreign Application Priority Data
Mar. 1, 2005 (FR) 05.020049

(51) Int. Cl. C25B 9/00; H05K 9/00

(52) U.S. Cl. 204/242; 307/91

(57) ABSTRACT

An electrical circuit for reducing electromagnetic fields in a vicinity of an electrolyzer, including an electrolyzer and an electrical line including at least one busbar for returning the current flowing through the electrolyzer, and a power supply of at least two rectifiers for delivering currents whose waveforms are phase-shifted with respect to each other.

The invention relates to electrolysers, especially to the power supply for such electrolysers.

The invention relates more especially to an electrical circuit for supplying rectified electric current to an electrolyser having bipolar electrodes.

It is common practice in the electrochemical industry to use electrolysers, in particular those having bipolar electrodes, which are supplied with DC current. Such electrolysers are widely used for electrolysing aqueous sodium chloride solutions, for the purpose of producing chlorine, aqueous sodium hydroxide solutions or aqueous sodium chlorate solutions.

Owing to the high current densities employed in electrolysers having bipolar electrodes, it is general practice to substitute DC current with rectified AC current. Rectified AC current normally has pulses whose frequency and amplitude depend on the rectifier used. Consequently, the electromagnetic field produced by the rectified AC current is liable to generate induced currents in an organism, the intensity of which currents may be relatively high in certain industrial applications, especially with bipolar electrolysers for the continuous production of chlorine and aqueous sodium hydroxide solutions.

It is also known that high electromagnetic fields may in extreme conditions have damaging consequences for a human organism, but particularly those produced by rectified AC current, because of the induced currents that they risk generating. It is consequently important to take measures to protect personnel in the vicinity of industrial installations or to reduce the magnitude of the electromagnetic fields therein. Moreover, standards have been enacted in this regard, imposing limitations on the magnitude of electromagnetic fields in industrial premises. Among these standards, European Standard 89/391/EEC is particularly strict.

It is one objective of the invention to provide an electrical circuit of novel design for supplying an industrial electrolyser with high-intensity electric current.

It is an objective of the invention in particular to provide an electrical circuit with which the electromagnetic field in the vicinity of the electrolyser is reduced to a sufficiently low value to meet the aforementioned European standard.

It is an objective of the invention more particularly to reduce the magnitude of the magnetic field along the gangways close to the side walls of electrolysers having bipolar electrodes.

Consequently, the invention relates to an electrical circuit for reducing the electromagnetic fields in the vicinity of an electrolyser, comprising the electrolyser and an electrical line comprising at least one busbar for the return of the current flowing through the electrolyser, characterized in that it comprises a power supply by means of at least two rectifiers preferably connected in parallel for delivering currents whose waveforms are out of phase with respect to one another. The electrical electrolysis circuit according to the invention is advantageously supplied with three-phase AC current.

The rectification of the three-phase AC current delivers a current whose oscillations have a base frequency six times higher than the fundamental frequency of the three-phase current (for example six times 50 Hz) . The use according to the invention of at least two rectifiers out of phase with respect to each other allows this frequency to be increased. Given the high intensity and the particular arrangement of the currents involved in the electrolysers, the circuit according to the invention allows the electromagnetic fields emitted in the vicinity of the installation to be substantially reduced.

In one advantageous embodiment of the circuit according to the invention, this comprises two rectifiers phase-shifted by between 29° and 31°, preferably by close to 30°. In this embodiment, current is obtained whose waveforms have a base frequency 12 times higher than the base frequency of the unrectified three-phase current.

The invention applies more specifically to electrolysers having substantially vertical bipolar electrodes. Such electrolysers are well known in the technical field, where they are widely used for electrolysing aqueous solutions of metal halides, especially sodium chloride. These electrolysers are generally formed from a succession of metal frames each comprising a bipolar electrode, these frames being juxtaposed in the manner of a filter press (Modern Chlor-alkali Technology, Volume 3, SCI, 1986, Chapter 13 “Operating experience gained with the bipolar Hoechst-Uhde membrane cell”; Modern Chlor-alkali Technology, Volume 4, SCI, 1990, Chapter 20 “Hoechst-Uhde single element membrane electrolyser: concept-experiences-applications”). The frames usually have a square or rectangular outline, so that they are juxtaposed in the manner of a filter press—they form an upper wall, a lower or bottom wall and two side walls of the electrolyser.

In a preferred embodiment of the electrical circuit according to the invention, the circuit further includes at least one drainage coil coupling the outputs of at least two rectifiers. The purpose of the drainage coil is to establish an anti-parallel reactance between the outputs of the rectifiers. Advantageously, the coil is formed by juxtaposition of iron plates and sheets, so as to limit heating losses. The outputs of the rectifiers penetrate the coil in opposite directions, so that a current perturbation present in one of the outputs induces an inverse perturbation in the current from the other output. When the two outputs are superimposed, what is thus obtained is a less perturbed total current.

In another preferred embodiment of the electrical circuit according to the invention, said electrical return current line comprises at least one busbar which is placed below or above the electrolyser. The choice of placing the busbar below or above the electrolyser is determined by considerations relating to the construction of the electrolyser and the mode of assembly of the bipolar electrodes. As a variant, the aforementioned electric current line may comprise one busbar placed below the electrolyser and another busbar placed above the electrolyser. In another variant, the electrolyser may also comprise several busbars under the electrolyser and several busbars above the electrolyser. In practice, for considerations relating to both assembly and maintenance of the electrolyser, it is generally preferred for the aforementioned electric current line not to include a busbar above the electrolyser.

It has been found that, all other things being equal, the electrical circuit according to the invention substantially reduces the electromagnetic field in the vicinity of the electrolyser having bipolar electrodes, mainly along the side walls of the latter, especially along the gangways that are usually present along these side walls and are used by operating and maintenance personnel.

In the electrical circuit according to the invention, the material of the busbar is not critical for the definition of the invention. It is generally made of copper, aluminium or an aluminium alloy.

In the electrical circuit according to the invention, the outline of the busbar cross section is not critical for the definition of the invention. For example, it may be square, rectangular, circular or polygonal.

In one particular embodiment of the electrical circuit according to the invention, the busbar has a rectangular outline and is oriented so that its large faces are approximately horizontal. It has been observed that, all other things being equal, by selecting a busbar of rectangular cross section, placed horizontally below and/or above the electrolyser, the magnitude of the electromagnetic field in the vicinity of the electrolyser is minimized. It has also been observed that the reduction in electromagnetic field in the vicinity of the electrolyser is greater the smaller the ratio of the thickness of the busbar to its width. In practice, it is consequently preferable to use, for the busbar, a flat metal plate. As a variant, it is possible to use several flat metal plates placed side by side below and/or above the electrolyser.

It has also been observed that, all other things being equal, the magnitude of the electromagnetic field in the vicinity of the electrolyser decreases when the busbar is brought up to the wall of the electrolyser.

Consequently, in another particular embodiment of the electrical circuit according to the invention, the busbar is placed in the immediate proximity of one wall of the electrolyser. In this embodiment of the invention, said wall of the electrolyser is the lower or bottom wall of the electrolyser or its upper wall, depending on whether the busbar is located below or above the electrolyser. In this embodiment of the invention, the expression “in the immediate proximity of the wall of the electrolyser” means that the distance between this wall and the busbar is at most equal to five times (preferably three times) the thickness of the busbar. Preferably, this distance does not exceed the thickness of the busbar.

In a preferred variant of this aforementioned embodiment of the invention, the busbar is fastened to said wall of the electrolyser. In this preferred embodiment variant of the invention, the busbar is advantageously a flat metal plate, one of the large faces of which is fastened to said wall, only the thickness of the necessary electrical insulation separating the busbar from the wall. The flat metal plate may be fastened to part of the area of said wall. Preferably, the flat metal plate is fastened to substantially the entire area of said wall.

In yet another particular embodiment of the invention, the aforementioned electrical line further includes two additional busbars, which are placed in the immediate proximity of two respective side walls of the electrolyser. In this embodiment of the invention, the expression “in the immediate proximity” is consistent with the definition given above for this expression.

All other things being equal, the presence of the additional busbars reduces the magnitude of the electromagnetic field in the vicinity of the electrolyser.

In this embodiment according to the invention, the additional busbars may have any shape compatible with the construction of the electrolyser. For example, they may have a square, rectangular, polygonal, oval or circular outline. The additional busbars may also have the same outline or different outlines, and they may have the same dimensions or different dimensions. In practice, it is preferred however for the additional busbars to have the same profile and the same dimensions. It is also preferable for the additional busbars to have a rectangular outline and for them to be fastened via their large face to the two respective side walls of the electrolyser.

In the embodiment of the invention that has just been described, the respective dimensions of the additional busbars and those of the or each busbar that is placed below and/or above the electrolyser are determined according to the manner in which it is desired to distribute the electric current within all of these busbars. In general, it is preferable for the intensity of the electric current in the busbar located below and/or above the electrolyser to be at least five times higher than the intensity of the electric current in each of the additional busbars.

In yet another embodiment of the invention, which is especially advantageous, the electric current return line of the electrical circuit is positioned so as to generate an electromagnetic field that is approximately symmetrical with respect to the vertical mid-plane of the electrolyser. In this embodiment, the desired objective (to generate an electromagnetic field that is approximately symmetrical with respect to the vertical mid-plane of the electrolyser) is achieved by dimensioning and positioning the or each busbar in a suitable manner. The choice of optimum dimensions and optimum position is determined by those skilled in the art, especially according to the shape and dimensions of the electrolyser. In practice, this result may generally be obtained by placing the busbar or busbars symmetrically with respect to the vertical mid-plane of the electrolyser.

In a final advantageous embodiment of the invention, a secondary electrical circuit is placed in the vicinity of the primary circuit. The current flows in the secondary circuit in the opposite direction for the purpose of generating a magnetic field that at least partly cancels out that created by the flow of the current in the primary circuit. The secondary circuit must therefore be capable of passing a current having an intensity close to that of the current flowing in the primary circuit. To obtain good compensation of the fields, the secondary circuit must be placed as best as possible in the vicinity of the primary circuit. It is recommended that one part of the secondary circuit be fastened to the electrolyser and preferably also for another part to be fastened to the busbar(s), in order to obtain optimum field compensation, taking into account the structural requirements that may necessitate the two circuits being spaced apart at certain points. It is possible to supply the secondary circuit by means of the power supply for the primary circuit, via an adjustment resistor. However, it is recommended for at least part of the secondary circuit that is in the vicinity of the return line to be supplied separately.

It is also recommended that the portion of the circuit located between the rectifiers and the electrolysers be configured so as to minimize the magnetic fields. In general, it is recommended that the current supply and return conductors be placed as close as possible to one another.

The electrical circuit according to the invention applies especially to electrolysers for continuous electrolysis of water or of aqueous solutions, such as aqueous alkali metal halide solutions, especially aqueous sodium chloride solutions. As a consequence, in a preferred embodiment of the invention, the electrolyser includes a pipe for the continuous inflow of an aqueous electrolyte and a pipe for the continuous outflow of a aqueous electrolyte.

The invention applies especially to electrolysers for the manufacture of sodium chlorate by electrolysis of aqueous sodium chloride solutions. The invention applies especially well to electrolysers for the manufacture of chlorine and aqueous sodium hydroxide solutions, by electrolysis of aqueous sodium chloride solutions, these electrolysers comprising cation permselective membranes that are interposed between the bipolar electrodes.

The electrical circuit according to the invention applies to any electrolysis installation that incorporates at least one electrolyser having vertical bipolar electrodes.

Consequently, the invention also relates to an electrolysis installation comprising at least one electrolyser having bipolar electrodes, that installation being connected to an electrical circuit according to the invention. The installation according to the invention may comprise a single electrolyser or several electrolysers electrically connected in series.

The invention relates in particular to the use of this installation, for the production of chlorine and aqueous sodium hydroxide solutions.

The electrical circuit according to the invention substantially reduces the electromagnetic field in the vicinity of the electrolysers, in particular of electrolysers having bipolar electrodes.

Consequently, the invention also relates to a method of reducing the electromagnetic fields in the vicinity of an electrical circuit comprising an electrolyser and an electrical line for returning the current, in which the circuit is supplied by means of at least two rectifiers for delivering currents whose waveforms are out of phase with respect to each other, preferably by 29° to 31°.

In a preferred variant of the method according to the invention, the circuit further includes at least one drainage coil coupling the outputs of at least two rectifiers.

In the method according to the invention, the circuit is also advantageously in accordance with the other various embodiments of the circuit according to the invention.

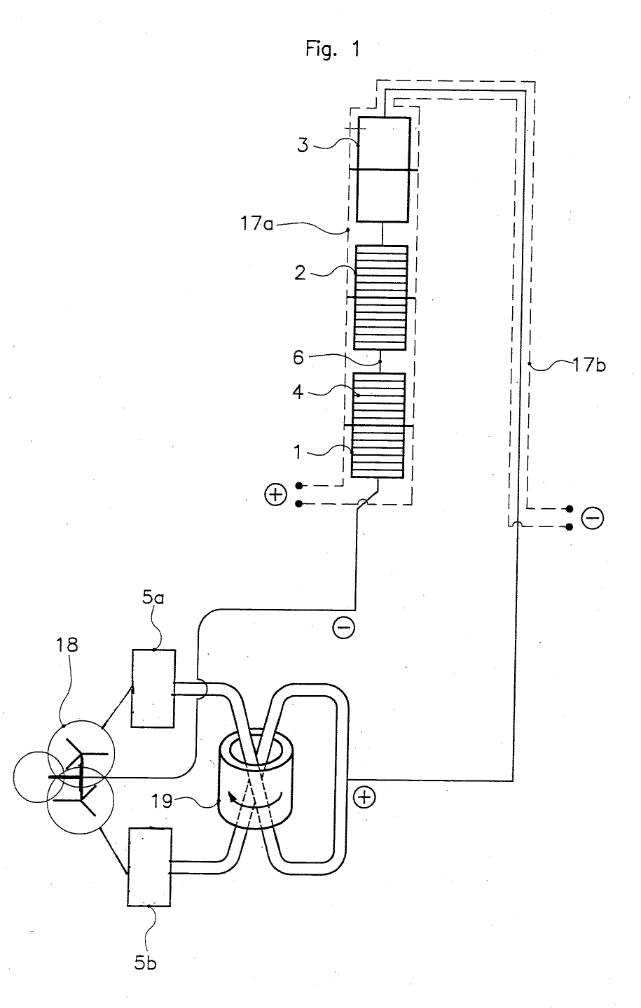

FIG. 1 shows, in plan view, the general diagram of an electrolysis installation in one particular embodiment of the invention.

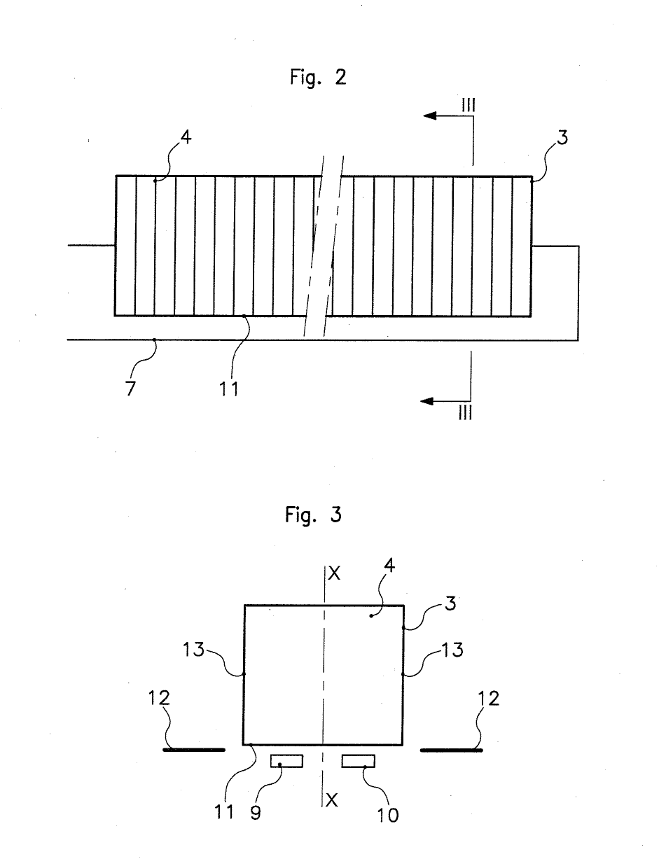

FIG. 2 is a schematic view, in longitudinal elevation, of another particular embodiment of the electrolysis installation according to the invention.

FIG. 3 is a vertical cross section in the plane III-III of FIG. 2.

FIG. 4 is a view similar to FIG. 3 of another embodiment of the installation according to the invention.

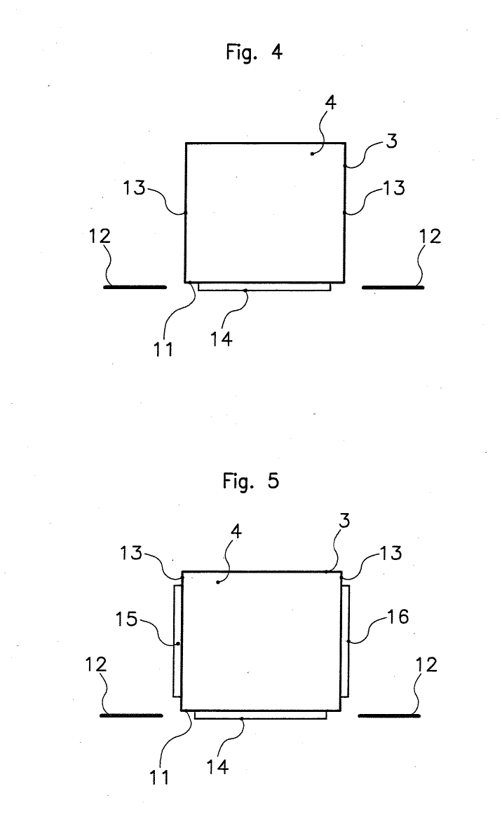

FIG. 5 is a preferred variant of the installation of FIG. 4.

In these figures, the same reference notations denote identical elements.

The electrolysis installation shown schematically in FIG. 1 comprises three electrolysers 1, 2 and 3 designed for the production of chlorine, hydrogen and sodium hydroxide by electrolysis of an aqueous sodium chloride solution. The electrolysers 1, 2 and 3 are of the vertical bipolar electrode type. They are formed by the juxtaposition of vertical rectangular frames 4, each containing a vertical bipolar electrode (not shown) . The frames 4 are juxtaposed in the manner of a filter press. Cation permselective membranes are interposed between the frames 4 in order to define an alternation of anode and cathode chambers. The anode chambers of the electrolysers 1, 2 and 3 are in communication with a pipe (not shown) for the continuous inflow of an aqueous sodium chloride solution. They are also in communication with a header (not shown) for continuous removal of chlorine. The cathode chambers of the electrolysers 1, 2 and 3 are in communication with two headers (not shown) which serve respectively for the continuous extraction of hydrogen on the one hand and of an aqueous sodium hydroxide solution on the other.

The electrolysers 1, 2 and 3 are electrically coupled in series via a drainage coil 19 to two rectifiers 5a and 5b by means of an electrical circuit comprising, on the one hand, busbars 6 interposed between the electrolysers 1, 2 and 3, and, on the other hand, an electric current return line 7 placed away from the electrolysers 1, 2, 3. The rectifiers 5a and 5b are supplied, with a phase shift of 30°, by an AC current source 18.

In the electrolysis installation shown in FIG. 1, the electric current return line 7 consists of a long busbar that runs along one longitudinal side wall of the electrolysers 1, 2 and 3.

In the electrolysis installation shown schematically in FIG. 1, each of the three electrolysers 1, 2, 3 may for example comprise 30 to 40 individual electrolysis cells, and the electrical supply comprises, for example, a 520 V DC rectifier capable of outputting a current ranging from 8 to 20 kA. This may result, depending on the area of the electrodes, in an anode current density ranging from 2.5 to 6 kA/m² of anode area. However, these numerical values are given purely by way of indication and do not limit the scope of the invention and of the claims that follow.

When the bipolar switch is closed, rectified electric current flows in succession through the electrolysers 1, 2, 3, through their bipolar electrodes and into the return line 7. This electric current generates an electromagnetic field in the environment of the installation.

According to the invention, the secondary circuit comprising segments 17a and 17b is placed in the vicinity of the electrolysers and of the return line. The installation shown schematically in FIGS. 2 and 3 illustrates one particular embodiment of the invention, in which the secondary circuit has not been shown. In these figures, only the electrolyser 3 has been shown. In the installation shown in FIGS. 2 and 3, the electric current return line 7 comprises two busbars 9 and 10 that are placed beneath the lower wall 11 of the electrolyser 3. The busbars 9 and 10 are prismatic bars made of metal that is a good electrical conductor (preferably copper or aluminium). These bars are placed symmetrically on either side of the vertical mid-plane X-X of the electrolyser. The busbars 9 and 10 are also placed in the vicinity of the lower wall 11 of the electrolyser 3. The effect of placing the busbars 9 and 10 in the manner shown in FIG. 3 is to reduce the magnitude of the electromagnetic field along the gangways 12 that run along the side walls 13 of the electrolyser 3 and are intended for the electrolyser maintenance personnel.

All other things being equal, it has been observed that the intensity of the electromagnetic field along the gangways 12 is reduced further when the busbars 9 and 10 are close to the mid-plane X-X and to the lower wall 11. It has also been observed that the magnitude of the electromagnetic field along the gangways 12 is reduced by decreasing the ratio of the thickness to the width of the busbars 9 and 10. It is therefore preferable to use flat horizontal plates or sheets for the busbars 9 and 10.

In the embodiment shown schematically in FIG. 4, in which the secondary circuit has not been shown either, the electric current return line 7 comprises a flat metal plate or sheet 14 that is fastened to the lower wall 11 of the electrolyser and covers substantially the entire area of this wall.

In the installation shown in FIG. 5, the electric current line 7 comprises a flat metal plate 14 that is applied against the lower wall 11 of the electrolyser 3 and two additional busbars 15 and 16 that run alongside the two respective side walls 13 of the electrolyser 3. The two additional busbars 15 and 16 are advantageously flat metal plates or sheets that are fastened to the side walls 13.

1-14. (canceled)

15: An electrical circuit for reducing electromagnetic fields in a vicinity of an electrolyzer, comprising:
an electrolyzer;
an electrical line comprising at least one busbar for return of current flowing through the electrolyzer; and
a power supply including at least two rectifiers for delivering currents whose waveforms are out of phase with respect to each other.

16: A circuit according to claim 15, wherein the currents are phase-shifted by between 29° and 31°.

17: A circuit according to claim 15, further comprising at least one drainage coil coupling outputs of the at least two rectifiers.

18: A circuit according to claim 15, wherein the busbar is positioned below and/or above the electrolyzer.

19: A circuit according to claim 18, wherein the busbar is fastened to a wall of the electrolyzer.

20: A circuit according to claim 19, wherein the wall is a bottom wall of the electrolyzer.

21: A circuit according to claim 19, wherein the busbar is a flat metal plate, one of large faces of which is fastened to the wall.

22: A circuit according to claim 15, wherein the electrical line further includes two additional busbars that are fastened to two respective side walls of the electrolyzer.

23: A circuit according to claim 15, wherein the electrical line is positioned so as to generate an electromagnetic field that is approximately symmetrical with respect to a vertical mid plane of the electrolyzer.

24: A circuit according to claim 15, wherein the electrolyzer includes a pipe for continuous inflow of an aqueous electrolyte and a pipe for continuous removal of an aqueous electrolyte.

25: A circuit according to claim 24, wherein the electrolyzer comprises cation permselective membranes that are interposed between bipolar electrodes.

26: A circuit according to claim 15, wherein a secondary electrical circuit is positioned in the vicinity of the electrolyzer and of the electrical line, for a current to flow in an opposite direction to that of current flowing in the electrolyzer.

27: A method of reducing electromagnetic fields in a vicinity of an electrical circuit including an electrolyzer and an electrical line for returning a current, wherein the circuit is supplied by at least two rectifiers for delivering currents whose waveforms are phase-shifted with respect to each other, the rectifiers being connected in parallel.

28: A method according to claim 27, wherein the circuit further includes at least one drainage coil coupling outputs of the at least two rectifiers.
